(19) United States
(12) Patent Application Publication
(10) Pub. No.: US 2026/0150681 A1
(43) Pub. Date: May 28, 2026

(54) SEMICONDUCTOR PACKAGE ASSEMBLY WITH A WATER COOLING SYSTEM

(71) Applicant: STATS ChipPAC Management Pte. Ltd., Singapore (SG)

(72) Inventor: JiSeon LEE, Incheon (KR)

(21) Appl. No.: 19/396,372

(22) Filed: Nov. 21, 2025

(30) Foreign Application Priority Data
Nov. 22, 2024 (CN) 202411685332.8

(51) Int. Cl. H01L 23/473; H01L 23/00; H01L 23/28

(52) U.S. Cl. CPC H10W 40/47; H10W 74/00; H10W 90/736

(57) ABSTRACT

A semiconductor package assembly, comprising: a substrate; an interposer mounted on a front surface of the substrate via a set of interconnect structures; at least one frontside semiconductor element mounted on a front surface of the interposer; at least one backside semiconductor element mounted on a back surface of the interposer, wherein the at least one backside semiconductor element is spaced apart from the substrate by the set of interconnect structures to define therebetween a gap; a backside cooling device mounted in the gap between the at least one backside semiconductor element and the substrate, wherein the backside cooling device is thermally coupled to the at least one backside semiconductor element; and a frontside cooling device mounted on and thermally coupled to the at least one frontside semiconductor element.

### TECHNICAL FIELD

The present application generally relates to semiconductor technologies, and more particularly, to a semiconductor package assembly with a water-cooling system, and a method for making a semiconductor package assembly.

### BACKGROUND OF THE INVENTION

The semiconductor industry is constantly faced with complex integration challenges as consumers want their electronics to be smaller, faster and higher performance with more and more functionalities packed into a single device. In some semiconductor packages, a Package-in-Package (PiP) or Package-on-Package (PoP) process is applied, which combines two or more integrated circuit (IC) packages together. The PiP or PoP devices can more efficiently use space and reduce lengths of signal paths between the packages. In a typical PiP or PoP device, one or more pre-molded semiconductor packages may be mounted onto another semiconductor package through an interposer or other similar structures.

However, it is noted that certain electronic components such as logic circuit chips in the PiP or PoP devices may generate significant heat during operation, which may not be well dissipated to the external environment due to the compact package structure of the PiP or PoP devices. Therefore, a need exists for further improvement to semiconductor package assemblies with integrated electronic components.

### SUMMARY OF THE INVENTION

An objective of the present application is to provide a semiconductor package assembly with a water-cooling system.

According to an aspect of the present application, a semiconductor package assembly is disclosed. The semiconductor package assembly comprises: a substrate; an interposer mounted on a front surface of the substrate via a set of interconnect structures; at least one frontside semiconductor element mounted on a front surface of the interposer; at least one backside semiconductor element mounted on a back surface of the interposer, wherein the at least one backside semiconductor element is spaced apart from the substrate by the set of interconnect structures to define therebetween a gap; a backside cooling device mounted in the gap between the at least one backside semiconductor element and the substrate, wherein the backside cooling device is thermally coupled to the at least one backside semiconductor element; and a frontside cooling device mounted on and thermally coupled to the at least one frontside semiconductor element.

According to another aspect of the present application, a method for making a semiconductor package assembly is provided. The method comprises: providing an interposer package, wherein the interposer package comprises an interposer, at least one frontside semiconductor element mounted on a front surface of the interposer, a frontside cooling device mounted on and thermally coupled to the at least one frontside semiconductor element, and at least one backside semiconductor element and a set of interconnect structures mounted on a back surface of the interposer; and wherein the set of interconnect structures have a height greater than that of the at least one backside semiconductor element; providing a substrate having on its frontside a backside cooling device; and mounting the interposer package onto the substrate via the set of interconnect structures and the backside cooling device, to thermally couple the backside cooling device with the at least one backside semiconductor element.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a semiconductor package assembly according to an embodiment of the present application.

FIG. 1B is a top view illustrating a backside layout of an interposer of the semiconductor package assembly shown in FIG. 1A.

FIG. 1C is a perspective view illustrating a backside cooling device of the semiconductor package assembly shown in FIG. 1A.

FIG. 2 illustrates a semiconductor package assembly according to another embodiment of the present application.

FIG. 3 illustrates a semiconductor package assembly according to a further embodiment of the present application.

FIGS. 4A to 4F illustrate a method for making a semiconductor package assembly according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, conventional semiconductor package assemblies may not have satisfactory heat dissipation performance due to their compact structure as well as significant heat generated by electronic components encapsulated within the semiconductor package assemblies. To address the heat dissipation issue, the inventors of the present application have conceived a method of incorporating into a semiconductor package assembly a cooling system such as a water-cooling system to provide cooling for the internal electronic components of the package assembly. In some embodiments, the cooling system may include a backside cooling pipe and a frontside cooling pipe mounted on both sides of an interposer module of the package assembly, which may be in fluid communication with each other and further to a heat radiator, to allow heat to be transferred from the internal electronic components to the external environment. Alternatively, a heat dissipation plate or other suitable passive heat dissipation devices may be mounted on the front side of the interposer module instead of the frontside cooling pipe. In this way, the heat dissipation performance of the semiconductor package assembly can be improved significantly.

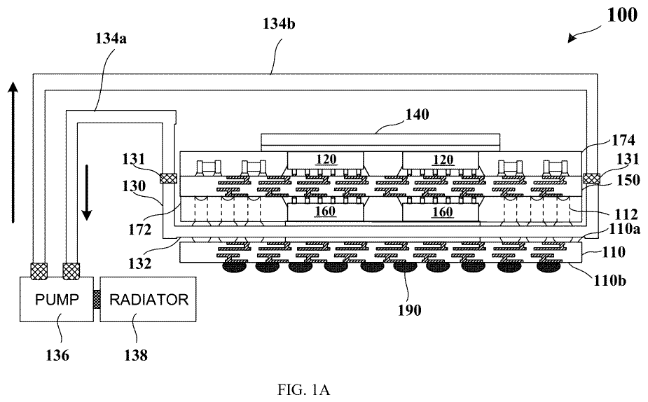

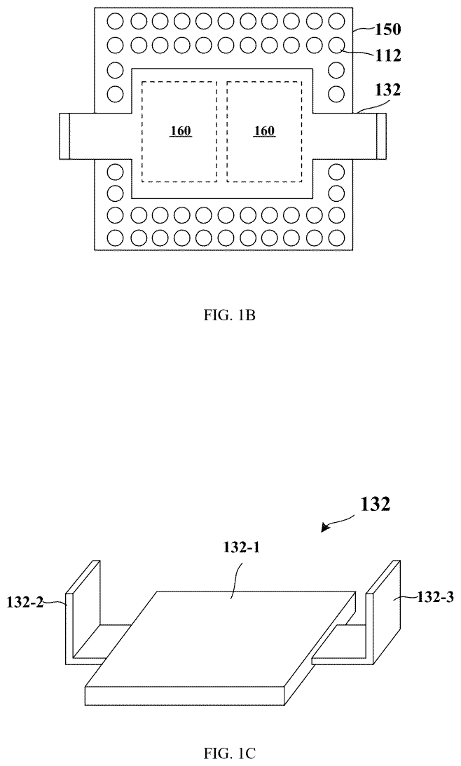

FIG. 1A illustrates a semiconductor package assembly 100 according to an embodiment of the present application. As shown in FIG. 1A, the semiconductor package assembly 100 includes two cooling devices, each thermally coupled to a group of semiconductor elements which are mounted on a side of an interposer of the semiconductor package assembly 100. As the two cooling devices are coupled to the two groups of semiconductor elements, respectively, heat generated by the semiconductor elements within the semiconductor package assembly 100 can be dissipated out of the package assembly efficiently. It should be noted that although four semiconductor elements are illustrated in FIG. 1A as an example, more semiconductor elements may be integrated within the semiconductor package assembly 100, as desired.

As shown in FIG. 1A, the semiconductor package assembly 100 includes a substrate 110, and an interposer 150 which is mounted on a front surface of the substrate 110 via a set of interconnect structures 112. The interconnect structures 112 can provide not only mechanical support but also electrical connection for the interposer 150. At least one frontside semiconductor element 120 is mounted on a font surface of the interposer 150, and at least one backside semiconductor element 160 is mounted on a back surface of the interposer 150. The at least one backside semiconductor element 160 mounted on the back surface of the interposer 150 is spaced apart from the substrate 110 because the set of interconnect structures 112 define a gap between the substrate 110 and the interposer 150, which generally has a height the same as a height difference between the interconnection structures 112 and the backside semiconductor elements 160 or a highest one of the backside semiconductor elements 160. It can be appreciated that during operation, the semiconductor elements 120 and 160 may generate heat that are desired to be dissipated out of the semiconductor package assembly 100.

In particular, a backside cooling device 130 is mounted in the gap between the substrate 110 and the backside semiconductor element 160, and is thermally coupled to the at least one backside semiconductor element 160 via a thermal interface material (TIM) layer, for example. The backside cooling device 130 may provide a heat pathway through the gap from the backside semiconductor elements 160 to the external environment. Furthermore, a frontside cooling device 140 is mounted on a front surface of the at least one frontside semiconductor element 120 via a TIM layer. Different from the backside cooling device 130 embedded within the semiconductor package assembly 100, the frontside cooling device 140 may be mounted topmost of the entire semiconductor package assembly 100 and thus be exposed to the external environment. As such, a shorter heat dissipation pathway may be provided by the frontside cooling device 140, compared to the heat dissipation pathway provided by the backside cooling device 130.

Still referring to FIG. 1A, a backside encapsulant 172 is formed on the back surface of the interposer 150 to at least partially encapsulate the set of interconnect structures 112 and the at least one backside semiconductor element 160. The backside encapsulant 172 can provide structural support for the set of interconnect structures 112 and the at least one backside semiconductor element 160. Specifically, the backside encapsulant 172 may expose respective front surfaces of one or more of the backside semiconductor elements 160, i.e., only lateral surfaces of the one or more backside semiconductor element 160 are covered by the backside encapsulant 172. The exposed front surfaces of the one or more backside semiconductor element 160 provide an interface for heat transferred or dissipated to the backside cooling device 130 and further to the external space, which will be later described. In some embodiments, the backside encapsulant 172 may be formed with an excess amount of a molding material over the at least one backside semiconductor element 160, which may later be attenuated (e.g., etched) to some extent to expose the front surfaces of the at least one backside semiconductor element 160. Preferably, the exposed surfaces of the backside semiconductor elements 160 may be at the same level relative to the back surface of the interposer 150, to facilitate mounting of the backside cooling device 130 with them. In some embodiments, the backside encapsulant 172 may be made, partially or in all, of a polymer composite material such as epoxy resin with filler, epoxy acrylate with filler, or polymer with proper filler.

Similar as the backside encapsulant 172, the semiconductor package assembly 100 further includes a frontside encapsulant 174 formed on the front surface of the interposer 150 to at least partially encapsulate the at least one frontside semiconductor element 120. As described above, the exposed front surfaces of the at least one frontside semiconductor element 120 provide an interface for heat transferred or dissipated to the frontside cooling device 140 and further to the external space, which will be described subsequently. The at least one frontside semiconductor element 120 may be mounted on the front surface of the interposer 150 via solder bumps or similar structures. In some other embodiments, other than those components on the front surface of the interposer 150, one or more other electronic components such as resistors, inductors, capacitors or other similar discrete devices, or smaller semiconductor elements, may be mounted on the front surface of the interposer 150.

The at least one frontside semiconductor element 120 and the at least one backside semiconductor element 160 may include any of a variety of types of semiconductor dice, semiconductor packages, or discrete devices. For example, the at least one frontside semiconductor element 120 and the at least one backside semiconductor element 160 may include a logic circuit chip such as a central processing unit (CPU) or a graphics processing unit (GPU), a memory device such as a high bandwidth memory (HBM), a digital signal processor (DSP), a radiofrequency (RF) circuit, a wireless baseband system-on-chip (SoC) processor, a sensor, an application specific integrated circuit, etc. The at least one frontside semiconductor element 120 and the at least one backside semiconductor element 160 may be passive components such as resistors, capacitors, inductors, switches, or any other suitable electronic devices. The interposer 150 can provide support and connectivity for electronic components and devices mounted thereon. For example, conductive wires such as redistribution layers may be formed in the interposer 150, with exposed patterns serving as conductive patterns where the electronic components and devices can be connected.

As aforementioned, the backside cooling device 130 is thermally coupled to the at least one backside semiconductor element 160. In the embodiment, the backside cooling device 130 includes a backside cooling pipe 132 for containing a coolant liquid such as water flowing therein to transfer heat generated by the at least one backside semiconductor element 160 to the external environment of the semiconductor package assembly 100. A pipe 134a is used to couple an outlet of the backside cooling pipe 132 to a pump 136, and another pipe 134b is used to couple an inlet of the backside cooling pipe 132 to the pump 136 or another pump. According to the configuration of the pump 136, the pipe 134b can bring the coolant liquid into the backside cooling pipe 132 and the pipe 134a can bring the coolant liquid out of the backside cooling pipe 132, thereby circulating the coolant liquid within the pipes 134a and 134b and the backside cooling pipe 132. In some embodiments, the backside cooling pipe 132 and the pipes 134a and 134b may include polyvinyl chloride (PVC), polyurethane (PU), polyethylene terephthalate glycol (PETG), metal such as copper or aluminum, etc. In some embodiments where the pipes 132, 134a and 134b are made of metal or similar conductive materials, electrical isolation between the pipes and the interconnect structures 112, conductive patterns and other electrically conductive structures or components can be implemented by, for example, adding insulating materials or routing and placing the pipes.

Referring to FIG. 1B, a top view illustrating a backside layout of the interposer 150 shown in FIG. 1A is provided. It can be appreciated that the backside layout of the interposer 150 may be similar as a frontside layout of the substrate 110 as they are aligned and connected with each other via the interconnect structures. In particular, the set of interconnect structures 112 are mounted on the interposer 150 and may be arranged around the at least one backside semiconductor element 160, and thus may not be in direct contact with the backside cooling device 132. Moreover, the backside cooling device 130 can have enlarged portions close to the backside semiconductor elements 160 to allow for better thermal communication therewith.

Referring to FIG. 1C, a perspective view illustrating the backside cooling pipe 132 is provided. As shown in FIGS. 1A and 1C, the backside cooling pipe 132 includes a heat exchange portion 132-1 which can be horizontal to the interposer when mounted with the interposer, and a first guide portion 132-2 and a second guide portion 132-3 at two opposite sides of the heat exchange portion 132-1. The first and second guide portions 132-2 and 132-3 can be for example perpendicular to the interposer and to the heat exchange portion 132-1. In particular, the heat exchange portion 132-1 may have a rectangular shape, which corresponds to the shapes or layout of the at least one backside semiconductor element 160. It can be appreciated that the heat exchange portion 132-1 may have other shapes, such as a zigzag shape or a spiral shape. In some embodiments, the backside cooling pipe 132 may have a height the same as the gap between the backside semiconductor element 160 and the substrate 110. Thus, the substrate 110 and the at least one backside semiconductor element 160 can be thermally coupled to a lower surface and an upper surface of the heat exchange portion 132-1 of the backside cooling pipe, respectively. However, in some other embodiments, the substrate 110 may not be in direct contact with the backside cooling pipe 132 as there may be no heat-generation element mounted thereon which requires heat dissipation. Also, the first guide portion 132-2 and the second guide portion 132-3 are in fluid communication with the heat exchange portion 132-1, serving as liquid guides between the heat exchange portion 132-1 and the pipes 134a and 134b. The guide portions 132-2 and 132-3 may have a smaller width than the heat exchange portion 132-1 so that they may not take up too much area of the interposer 150, which may be needed for the mounting of the interconnect structures 112. In particular, the first guide portion 132-2 may serve as an outlet of the backside cooling pipe 132 to discharge the coolant liquid from the heat exchange portion 132-1 to dissipate heat to the external environment, e.g., to a coolant pool or tank, and the second guide portion 132-3 may serve as an inlet of the backside cooling pipe 132 to receive the coolant liquid which has a lower temperature.

However, the backside cooling pipe 132 is not limited to the structure and configuration illustrated in FIGS. 1B and 1C. In some other embodiments, the heat exchange portion 132-1 may include a plurality of branches extending between the first guide portion 132-2 and the second guide portion 132-3, or have a zigzag shape which meanders between the first guide portion 132-2 and the second guide portion 130-3. It can be appreciated that the cooling pipe 132 may take other suitable shapes to increase its contact area with the at least one backside semiconductor element 160, or further with the substrate 110.

With continued reference to FIG. 1A, the set of interconnect structures 112 are formed between the substrate 110 and the interposer 150 to electrically connect the electronic components mounted thereon. In an embodiment, the set of interconnect structures 112 may be solder bumps, while in some alternative embodiments, the set of interconnect structures 112 may be other interconnect components such as metal posts or e-bar modules. Besides electrically connecting the substrate 110 and the interposer 150 with each other, the set of interconnect structures 112 may provide mechanical support therebetween. In particular, the set of interconnect structures 112 may extend through the backside encapsulant 172 and protrude from the back surface of the backside encapsulant 172 (i.e., the back surface of the at least one backside semiconductor element 160). In this way, a gap may be formed between the at least one backside semiconductor element 160 and the substrate 110. In other words, the set of interconnect structures 112 are so formed that the backside cooling device 130 are mounted in the gap where the coolant liquid may be filled and flow, which will be described specifically in the following.

It can be appreciated that the at least one backside semiconductor element 160 may have different heights when they are mounted on the interposer 150, of which the highest one or ones may need cooling by the backside cooling device 130 and thus be exposed and other backside semiconductor element generating fewer heat may be encapsulated entirely. Also, in some embodiments, the position of the semiconductor elements may be changed between the at least one frontside semiconductor element 120 and the at least one backside semiconductor element 160, depending on the specific electronic components encapsulated in the package, or particularly respective maximum junction temperatures acceptable to the electronic components. For example, a HBM element or module may withstand a maximum junction temperature of 85 to 95 Centi-degrees, while a generic logic circuit die may withstand a maximum junction temperature of 120 Centi-degrees. In that case, the HBM element or module may be disposed closer to an inlet of the backside cooling pipe 132, while the generic logic circuit die may be disposed farther away from the inlet. As such, after flowing through the HBM element or similar relatively low temperature elements, the coolant liquid can flow further through the logic circuit die or similar relatively high temperature elements and absorb heat from them.

Still referring to FIG. 1A, two valves 131 may be disposed at the inlet and the outlet of the backside cooling pipe 132, respectively, to regulate a flow rate of the coolant liquid flowing within the backside cooling pipe 132. For example, when the semiconductor package assembly 100 is operating at a higher power, i.e., more heat may be generated during operation, the valves 131 may be regulated to increase the flow rate of the coolant liquid. In contrast, when the semiconductor package assembly 100 is operating at a lower power, i.e., less heat may be generated during operation, the valves 131 may be regulated to decrease the flow rate of the coolant liquid. As shown in FIG. 1A, a radiator 138 is coupled to the pump 136 to cool the coolant liquid when it comes out through the pump 136. The radiator 138 may be a passive radiator or an active radiator, which can cool the coolant liquid down to a lower temperature, e.g. the room temperature. Therefore, the coolant liquid in the backside cooling pipe 132 may be circulated (represented by arrows in FIG. 1A) and cooled down efficiently through the pump 136 and the radiator 138.

As aforementioned, the at least one frontside semiconductor element 120 can be exposed from the frontside encapsulant 174. In some embodiments, the frontside cooling device 140 may include a heat dissipation plate such as a metal plate attached onto the at least one frontside semiconductor element 120 via a TIM layer to allow heat exchange from the frontside semiconductor elements 120 to the external environment. In this way, heat generated by both the frontside semiconductor elements 120 and the backside semiconductor elements 160 can be transferred out of the semiconductor package assembly 100 at the same time.

The substrate 110 has a front surface 110a and a back surface 110b that is opposite to the front surface 110a. Conductive bumps 190 may be mounted onto the back surface 110b of the substrate 110 to allow the entire semiconductor package assembly 100 to be mounted on or connected to an external device when needed. By way of example, the substrate 110 may include a printed circuit board (PCB), a carrier substrate, a semiconductor substrate with electrical interconnections, a ceramic substrate, a laminate interposer, a strip interposer, a leadframe, or other suitable substrates. The substrate 110 may include any structure on or in which an integrated circuit system can be fabricated. In some examples, the substrate 110 may include redistribution structures having one or more dielectric layers and one or more conductive layers between and through dielectric layers. The conductive layers may define pads, traces and plugs through which electrical signals or voltages can be distributed horizontally and vertically across the redistribution structures.

In the example shown in FIG. 1A, the conductive bumps 190 are illustrated as solder bumps, but the present application is not limited thereto. In some other embodiments, the conductive bumps 190 may include conductive pillars, copper balls, etc. In a case where the semiconductor package assembly 100 is mounted on an external device or substrate such as a printed circuit board (PCB), the conductive bumps 190 may be used for electrically connecting the semiconductor package assembly 100 to the external device or substrate.

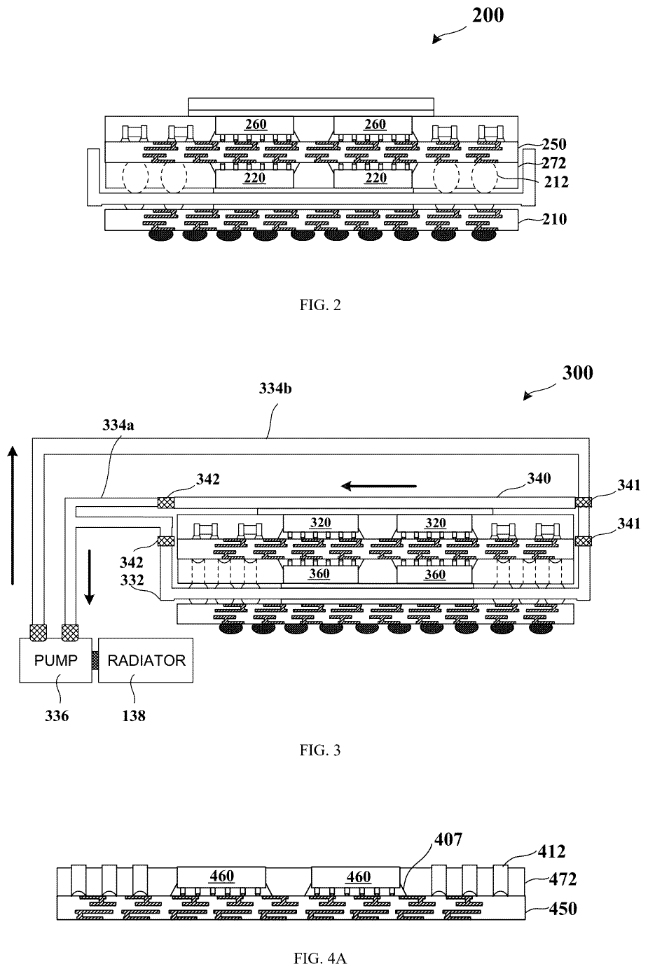

Various modifications can be made to the semiconductor package assembly 100 shown in FIG. 1A. FIGS. 2 and 3 illustrate two semiconductor package assemblies 200 and 300 according to other embodiments of the present application, respectively, with certain changes to the semiconductor package assembly 100 shown in FIG. 1A.

In the example shown in FIG. 2, interconnect structures 212 are solder balls that extend between an interposer 250 and a substrate 210. The solder balls 212 can preformed on the interposer 250 or the substrate 210, and be encapsulated by a backside encapsulant 272. The interconnect structures 212 can provide mechanical support and electrical connection between the interposer 250 and the substrate 210. The similar or same parts between the semiconductor package assembly 200 and the semiconductor package assembly 100 shown in FIG. 1A will not be repeated herein.

In the semiconductor package assembly 300 shown in FIG. 3, a frontside cooling device mounted on frontside semiconductor elements 320 includes a frontside cooling pipe 340 for containing a coolant liquid flowing therein to transfer heat generated by at least one frontside semiconductor element 320 to the external environment of the semiconductor package assembly 300, similar as a backside cooling pipe 332 which is mounted onto backside semiconductor elements 360. Accordingly, a set of inlet valves 341 and a set of outlet valves 342 may be in fluid communication with the frontside cooling pipe 340 and the backside cooling pipe 332. A pump 336 can be in fluid communication with the frontside cooling pipe 340 and the backside cooling pipe 332 to circulate the coolant liquid within the frontside cooling pipe 340 and the backside cooling pipe 332. It should be appreciated that although the backside cooling pipe 332 and the frontside cooling pipe 340 are connected by a set of pipes 334a and 334b in this embodiment, there are other ways of flowing the coolant liquid. For example, the cooling pipes 332 and 340 may be connected to separate valves, pumps and even separate coolant containers. In this way, the coolant liquid can flow within the fluid pathway including the frontside and backside cooling pipes to dissipate heat generated by the internal electronic components out of the semiconductor package assembly 300.

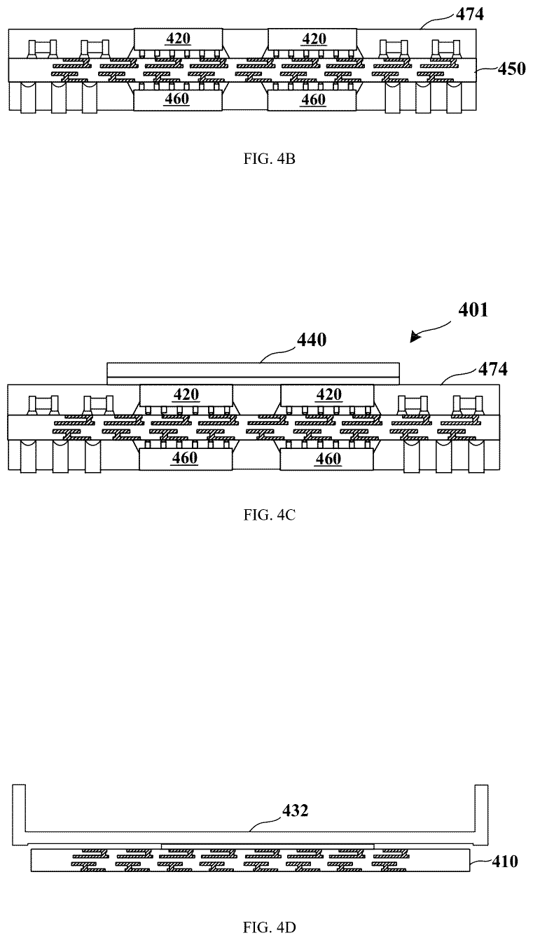

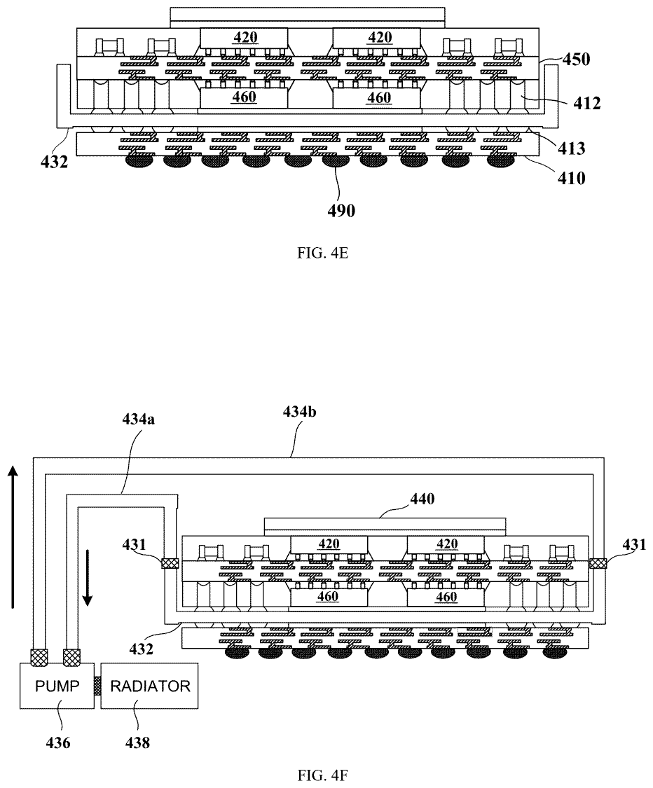

FIGS. 4A to 4F illustrate a method for making a semiconductor package assembly according to an embodiment of the present application. The method may be used to make the semiconductor package assembly 100 shown in FIG. 1A, or may be used to make the semiconductor package assembly 200 shown in FIG. 2 or the semiconductor package assembly 300 shown in FIG. 3 with some modifications.

As shown in FIG. 4A, an interposer 450 is provided, and at least one backside semiconductor element 460 is mounted onto the interposer 450 via solder bumps. An underfill material 407 may be filled between the at least one backside semiconductor element 460 and the interposer 450 and around solder bumps for the at least one backside semiconductor element 460, to enhance the attachment of the at least one backside semiconductor element 460 to the interposer 450. Furthermore, a backside encapsulant 472 may be formed on the interposer 450 to encapsulate the at least one backside semiconductor element 460 and a set of interconnect structure 412. For example, the backside encapsulant 472 may be formed using an injection molding process or a compression molding process. In some other embodiments, the backside encapsulant 472 may be formed using paste printing, transfer molding, liquid encapsulant molding, vacuum lamination, spin coating, or any other suitable process. An excess portion of the molding material of the backside encapsulant 472 that is higher than a back surface of the at least one backside semiconductor element 460 may be removed, for example, using a grinding process and other suitable etching processes, to expose the back surface of the at least one backside semiconductor element 460 and set of interconnect structure 412.

Next, as shown in FIG. 4B, the interposer 450 may be flipped over, with the front surface of the interposer 450 facing upward. At least one frontside semiconductor element 420 is mounted onto the front surface of the interposer 450 via solder bumps. A frontside encapsulant 474 may be formed on the front surface of the interposer 450 to encapsulate the at least one frontside semiconductor element 420. An excess portion of the molding material of the frontside encapsulant 474 that is higher than at least one frontside semiconductor element 420 may be removed.

Next, as shown in FIG. 4C, a frontside cooling device 440 is stacked on a front surface of the at least one frontside semiconductor element 420 via a TIM layer to cover the at least one frontside semiconductor element 420. It should be noted other forms of the frontside cooling device besides the heat dissipation plate such as the frontside cooling pipe shown in FIG. 3 can be used instead. In that case, the frontside cooling pipe can be attached to the at least one frontside semiconductor element, with pipes that input coolant liquid into or out of the frontside cooling pipe. After the various steps shown in FIGS. 4A to 4C, an interposer package 401 can be obtained.

Next, as shown in FIG. 4D, a backside cooling pipe 432 is mounted onto the substrate 410, for example, via a TIM layer. In some embodiments, the backside cooling pipe 432 may be attached onto the substrate 410 via an additional adhesive material. Alternatively, the backside cooling pipe 432 may be mounted onto the substrate 410 via some small spacers or supports, such that the backside cooling pipe 432 may not be in direct contact with the substrate 410. In some optional embodiments, after the backside cooling pipe 432 is mounted, an encapsulant layer or similar structures may be formed on the substrate 410 to further improve the connection between the backside cooling pipe 432 and the substrate 410. It can be appreciated that the encapsulant layer may not take up an area of the substrate 410 where the interconnect structures may be later mounted or connected. Alternatively, the encapsulant layer may be formed later after the mounting of the interposer package 401 onto the substrate 410, similar as an underfill layer between the backside semiconductor elements 460 and the substrate 410.

Next, the interposer package 401 is mounted onto the substrate 410 via the backside cooling pipe 432 in FIG. 4E. A set of solder bumps may be formed and reflowed to form a set of interconnect structures 412 between the interposer 450 and the substrate 410. The interposer 450 includes at its back surface a set of conductive patterns which are aligned with another set of conductive patterns formed on the front surface of the substrate 410 such that the two sets of conductive patterns are electrically connected with each other through the set of interconnect structures 412. Afterwards, a plurality of conductive bumps 490 are formed on the back surface of the substrate 410. In the example shown in FIG. 4E, the conductive bumps 490 are illustrated as solder bumps, but the present application is not limited thereto. In some other embodiments, the conductive bumps 490 may include conductive pillars, copper balls, micro bumps, etc.

Next, as shown in FIG. 4F, a pump 436 is coupled to the semiconductor package assembly, which is in fluid communication with the backside cooling pipe 432 through cooling pipes 434a and 434b to circulate the coolant liquid within the backside cooling pipe 432. Further, a radiator 438 is coupled with the pump 436 to cool the coolant liquid. Two valves 431 are mounted in the backside cooling pipe 432 to regulate the flow of the coolant liquid within backside cooling pipe 432.

After the various steps shown in FIGS. 4a to 4f, the semiconductor package assembly can be obtained.

The discussion herein includes numerous illustrative figures that show various portions of a semiconductor package assembly with a direct cooling system and a method for making such semiconductor package assembly. For illustrative clarity, such figures do not show all aspects of each example semiconductor package. Any of the example packages provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package assembly, comprising:
a substrate;
an interposer mounted on a front surface of the substrate via a set of interconnect structures;
at least one frontside semiconductor element mounted on a front surface of the interposer;
at least one backside semiconductor element mounted on a back surface of the interposer, wherein the at least one backside semiconductor element is spaced apart from the substrate by the set of interconnect structures to define therebetween a gap;
a backside cooling device mounted in the gap between the at least one backside semiconductor element and the substrate, wherein the backside cooling device is thermally coupled to the at least one backside semiconductor element; and
a frontside cooling device mounted on and thermally coupled to the at least one frontside semiconductor element.

2. The semiconductor package assembly of claim 1, further comprising:
a backside encapsulant formed between the interposer and the substrate to at least partially encapsulate the set of interconnect structures and the at least one backside semiconductor element.

3. The semiconductor package assembly of claim 1, further comprising:
a frontside encapsulant formed on the front surface of the interposer to at least partially encapsulate the at least one frontside semiconductor element.

4. The semiconductor package assembly of claim 1, wherein the backside cooling device is further thermally coupled to the substrate, and wherein the backside cooling device is thermally coupled to the substrate and the at least one backside semiconductor element via a thermal interface material (TIM).

5. The semiconductor package assembly of claim 1, wherein the backside cooling device comprises a backside cooling pipe for containing a coolant liquid flowing therein to transfer heat generated by the at least one backside semiconductor element to an external environment of the semiconductor package assembly.

6. The semiconductor package assembly of claim 5, further comprising:
a pump in fluid communication with the backside cooling pipe to circulate the coolant liquid within the backside cooling pipe; and
a radiator in fluid communication with the pump to cool the coolant liquid.

7. The semiconductor package assembly of claim 5, wherein the frontside cooling device comprises a frontside cooling pipe for containing a coolant liquid flowing therein to transfer heat generated by the at least one frontside semiconductor element to the external environment of the semiconductor package assembly.

8. The semiconductor package assembly of claim 7, further comprising:
a pump in fluid communication with the frontside cooling pipe and the backside cooling pipe to circulate the coolant liquid within the frontside cooling pipe and the backside cooling pipe; and
a radiator in fluid communication with the pump to cool the coolant liquid.

9. The semiconductor package assembly of claim 5, wherein the at least one backside semiconductor element comprises a logic circuit semiconductor element and a memory circuit semiconductor element, and wherein the memory circuit semiconductor element is upstream of the logic circuit semiconductor element relative to the backside cooling pipe.

10. The semiconductor package assembly of claim 1, wherein the frontside cooling device comprises a heat dissipation plate attached onto the at least one frontside semiconductor element.

11. A method for forming a semiconductor package assembly, comprising:
providing an interposer package, wherein the interposer package comprises an interposer, at least one frontside semiconductor element mounted on a front surface of the interposer, a frontside cooling device mounted on and thermally coupled to the at least one frontside semiconductor element, and at least one backside semiconductor element and a set of interconnect structures mounted on a back surface of the interposer; and wherein the set of interconnect structures have a height greater than that of the at least one backside semiconductor element;
providing a substrate having on its front surface a backside cooling device; and
mounting the interposer package onto the substrate via the set of interconnect structures and the backside cooling device, to thermally couple the backside cooling device with the at least one backside semiconductor element.

12. The method of claim 11, wherein providing an interposer package further comprises:
mounting the at least one backside semiconductor element and the set of interconnect structures on the back surface of the interposer;
forming a backside encapsulant on the back surface of the interposer to at least partially encapsulate the at least one backside semiconductor element and the set of interconnect structures;
mounting the at least one frontside semiconductor element on the front surface of the interposer;
forming a frontside encapsulant on the front surface of the interposer to at least partially encapsulate the at least one frontside semiconductor element; and
mounting the frontside cooling device onto the at least one frontside semiconductor element.

13. The method of claim 11, wherein the backside cooling device comprises a backside cooling pipe for containing a coolant liquid flowing therein, and wherein providing a substrate having on its frontside a backside cooling device comprises:
mounting the backside cooling pipe onto the substrate.

14. The method of claim 11, wherein the frontside cooling device comprises a frontside cooling pipe for containing a coolant liquid flowing therein.

15. The method of claim 11, wherein the frontside cooling device comprises a heat dissipation plate attached onto the at least one frontside semiconductor element.

16. The method of claim 11, wherein the backside cooling device comprises a backside cooling pipe for containing a coolant liquid flowing therein, and wherein the method further comprises:
coupling a pump with the backside cooling pipe to circulate the coolant liquid within the backside cooling pipe; and
coupling a radiator with the pump to dissipate heat from the coolant liquid out of the backside cooling pipe.
